(19) United States
(12) Patent Application Publication
(10) Pub. No.: US 2016/0018487 A1
(43) Pub. Date: Jan. 21, 2016

(54) MAGNETIC RESONANCE IMAGING APPARATUS AND METHOD FOR CONTROLLING THE SAME

(71) Applicant: SAMSUNG ELECTRONICS CO., LTD., Suwon-si (KR)

(72) Inventors: Praveen GULAKA, Suwon-si (KR); Yang Lim CHOI, Seongnam-si (KR); Byoung Mock KAHM, Suwon-si (KR); Sung We PARK, Suwon-si (KR); Young Jae CHAE, Suwon-si (KR); Hyun Hee JO, Osan-si (KR)

(73) Assignee: SAMSUNG ELECTRONICS CO., LTD., Suwon-si (KR)

(21) Appl. No.: 14/804,408

(22) Filed: Jul. 21, 2015

(30) Foreign Application Priority Data
Jul. 21, 2014 (KR) 10-2014-0091627

(51) Int. Cl. G01R 33/30; G01R 33/385; G01R 33/28

(52) U.S. Cl. CPC G01R 33/307; G01R 33/283; G01R 33/385

(57) ABSTRACT

A magnetic resonance imaging apparatus having a display and a method for controlling the same are provided. A magnetic resonance imaging apparatus includes a magnet assembly; a transfer table configured to move into the magnet assembly or out of the magnet assembly; and a display configured to move into the transfer table or move out of the transfer table.

### CROSS-REFERENCE TO RELATED APPLICATION(S)

This application claims the benefit of Korean Patent Application No. 10-2014-0091627, filed on Jul. 21, 2014 in the Korean Intellectual Property Office, the disclosure of which is incorporated herein by reference in its entirety.

### BACKGROUND

1. Field

Exemplary embodiments relate to a Magnetic Resonance Imaging (MRI) apparatus and a method for controlling the same, and more particularly to an MRI apparatus including a display unit and a method for controlling the same.

2. Description of the Related Art

In general, an image processing apparatus (e.g., a medical imaging device) is a device which acquires information of a patient and provides an image of the acquired information. For example, the image processing apparatus includes an X-ray imaging device, an ultrasonic diagnostic device, a computed tomography (CT) scanner, a magnetic resonance imaging (MRI) apparatus, and the like.

The magnetic resonance imaging (MRI) apparatus among these devices provides a relatively free imaging condition, high contrast in soft tissue, and a variety of diagnostic information images. Accordingly, the magnetic resonance imaging (MRI) apparatus occupies a prominent place in the medical image diagnostic field.

The MRI apparatus causes nuclear magnetic resonance in the hydrogen atomic nuclei of the human body using a magnetic field harmless to humans and RF which is a type of non-ionizing radiation, to thereby image the densities and physical or chemical characteristics of the atomic nuclei.

Specifically, the magnetic resonance imaging (MRI) apparatus is an image diagnosis device that supplies a uniform frequency and energy to atomic nuclei in a state in which a uniform magnetic field is applied to the atomic nuclei and converts energy emitted from the atomic nuclei into a signal to diagnose the interior of the human body.

A proton constituting each atomic nucleus has spin angular momentum and a magnetic dipole. When a magnetic field is applied to atomic nuclei, therefore, the atomic nuclei are arranged in a direction of the magnetic field and perform precession about the direction of the magnetic field. Such precession enables images of the human body to be acquired through a nuclear magnetic resonance phenomenon.

Meanwhile, the MRI apparatus may take about 20˜60 minutes to acquire magnetic resonance (MR) images of the patient according to a scanning part and MR image categories. That is, MRI apparatuses may need a longer image capture time than other medical imaging apparatuses. The patient may experience anxiety due to a long image capture time.

In addition, the MRI apparatus places the patient into a bore formed by a magnet assembly so as to diagnose the patient. Accordingly, the patient located in the bore may feel fear or anxiety about imaging using the MRI apparatuses.

### SUMMARY

Therefore, it is an aspect of the exemplary embodiments to provide a magnetic resonance imaging (MRI) apparatus including a display unit such that the patient located in a bore can feel comfortable and can experience a sense of stability.

It is another aspect of the exemplary embodiments to provide a magnetic resonance imaging (MRI) apparatus including a display unit that is exposed to the outside in response to movement of a transfer table, thereby preventing breakdown of the display unit.

Additional aspects of the exemplary embodiments will be set forth in part in the description which follows and, in part, will be obvious from the description, or may be learned by practice of the exemplary embodiments.

In accordance with an aspect of the exemplary embodiments, a magnetic resonance imaging apparatus includes: a magnet assembly; a transfer table configured to move into the magnet assembly and out of the magnet assembly; and a display configured to move into the transfer table or move out of the transfer table.

The display may be configured to move into or out of the transfer table in response to movement of the transfer table.

At least a portion of the display may be provided in the transfer table. The display may be configured to move out of the transfer table in response to the transfer table moving into the magnet assembly.

The display may be configured to move into the transfer table in response to the transfer table moving out of the magnet assembly.

The transfer table may include a rotatably installed first sawtooth; and the display may include a third sawtooth corresponding to the first sawtooth.

The first sawtooth may be configured to rotate in response to movement of the transfer table; and the third sawtooth may be configured to rotate based on rotation of the first sawtooth and thereby move the display.

The magnetic resonance imaging apparatus may further include: a bore provided in the magnet assembly; and a transfer guide provided in the bore so as to guide movement of the transfer table, wherein the transfer guide includes a second sawtooth corresponding to the first sawtooth.

The transfer table may be configured to move along the transfer guide in a manner that the first sawtooth rotates based on movement of the second sawtooth; and the display may be configured to move based on rotation of a third sawtooth moving based on rotation of the first sawtooth.

The transfer table may include a reception housing which houses the display, wherein the reception housing is recessed at one side of the transfer table.

The display may be configured to move into and out of the reception housing.

At least one of the reception housing and the display may include a withdrawal sensor configured to detect whether the display is withdrawn from the reception housing.

The reception housing may include a rotatably installed first sawtooth; and the display may include a third sawtooth configured to move based on rotation of the first sawtooth.

The magnetic resonance imaging apparatus may further include: a bore formed in the magnet assembly, wherein one side of the first sawtooth contacts the third sawtooth, and the other side of the first sawtooth contacts a second sawtooth fixed at the inside of the bore.

The magnetic resonance imaging apparatus may further include: a bore formed in the magnet assembly, wherein the display includes a projector to display an image on an inside of the bore.

The projector may be installed in a manner that an image is displayed at one side of the bore located in a viewing direction of a patient on the transfer table.

The projector may be shielded from a magnetic field or an electric field contained in the bore.

The magnetic resonance imaging apparatus may further include: a bore formed in the magnet assembly, wherein the display is configured to display an image on the inside of the bore.

In accordance with another aspect of an exemplary embodiment, a method for controlling a magnetic resonance imaging apparatus having a magnet assembly in which a bore is formed includes: moving a transfer table from an outside of the bore to an inside of the bore; moving a display out of the transfer table in response to the moving of the transfer table to the inside of the bore; operating the display to display an image on the inside of the bore; capturing an image of an object located on the inside of the bore on the transfer table; moving the transfer table from the inside to the outside of the bore; and moving the display into the transfer table in response to the moving of the transfer table to the outside of the bore.

The moving of the transfer table to the inside of the bore may include moving the transfer table along a transfer guide located in the bore; and the moving of the transfer table to the outside of the bore may include moving the transfer table along the transfer guide.

The transfer table may include a rotatably installed first sawtooth; and the transfer table may be configured to move along the transfer guide in a manner that the first sawtooth rotates based on movement of a second sawtooth provided at the transfer guide.

The display may include a third sawtooth configured to rotate based on rotation of the first sawtooth.

The display may include a projector configured to display an image on the inside of the bore.

The method may further include: determining whether at least a portion of the display is exposed to the outside of the transfer table.

### BRIEF DESCRIPTION OF THE DRAWINGS

These and/or other aspects of the exemplary embodiments will become apparent and more readily appreciated from the following description of the exemplary embodiments, taken in conjunction with the accompanying drawings of which:

FIG. 1 is a block diagram illustrating a magnetic resonance imaging (MRI) apparatus according to an exemplary embodiment;

FIG. 2 is a view schematically illustrating an external appearance of the magnetic resonance imaging (MRI) apparatus according to an exemplary embodiment;

FIG. 3 is a view illustrating a space in which an object is placed, in the X-axis, Y-axis, and Z-axis;

FIGS. 4A and 4B are views illustrating a configuration of a magnet assembly and a configuration of gradient coils of the MRI apparatus according to an exemplary embodiment;

FIG. 5 shows a gradient coil unit and a pulse sequence for use in the MRI apparatus;

FIGS. 6A, 6B and 6C show a display unit of the MRI apparatus according to an exemplary embodiment;

FIGS. 7A and 7B show a display unit installed at a transfer table of the MRI apparatus according to an exemplary embodiment;

FIG. 8 shows a reception unit, a display unit, and a second sawtooth of the MRI apparatus according to an exemplary embodiment;

FIG. 9 shows the display unit of the MRI apparatus according to an exemplary embodiment;

FIG. 10 is a view illustrating the reception unit of the MRI apparatus according to an exemplary embodiment;

FIGS. 11A, 11B and 11C are conceptual diagrams illustrating movement of the display unit of the MRI apparatus according to an exemplary embodiment;

FIG. 12 is a control block diagram illustrating the MRI apparatus according to an exemplary embodiment; and

FIG. 13 is a flowchart illustrating a method for controlling the MRI apparatus according to an exemplary embodiment;

### DETAILED DESCRIPTION

Reference will now be made in detail to the exemplary embodiments, examples of which are illustrated in the accompanying drawings, wherein like reference numerals refer to like elements throughout.

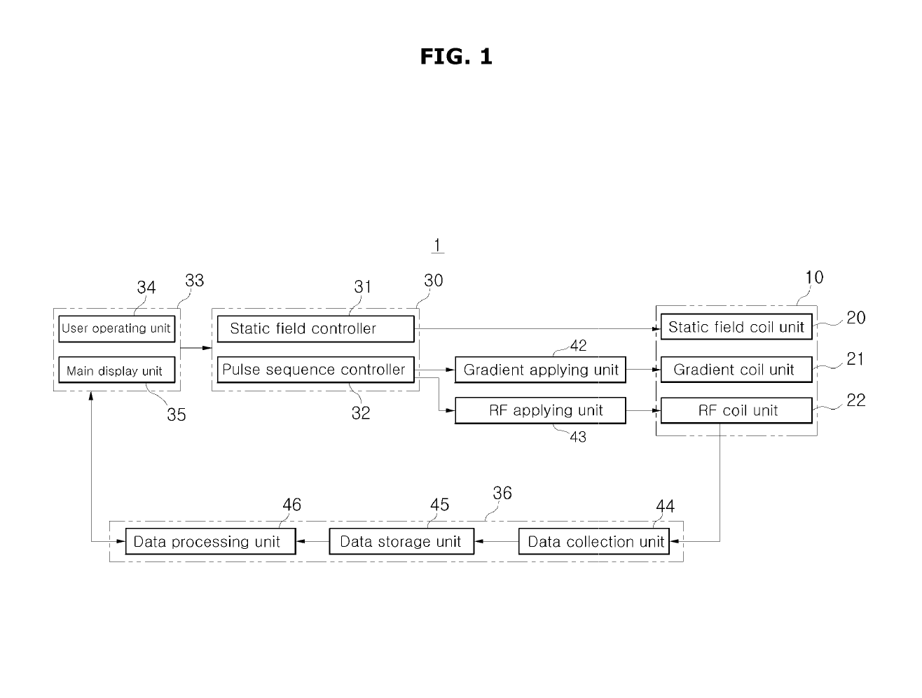

FIG. 1 is a block diagram illustrating a magnetic resonance imaging (MRI) apparatus according to an exemplary embodiment;

Referring to FIG. 1, the MRI apparatus 1 may include a magnet assembly 10, a controller 30, an image processing unit 36 (e.g., image processor), and other components described below.

The magnet assembly 10 may create a magnetic field and cause resonance of atomic nuclei. The magnet assembly may include a static field coil unit 20 (e.g., static field coil), a gradient coil unit 21 (e.g., gradient coil), and a radio frequency (RF) coil unit 22 (e.g., RF coil).

The static field coil unit 20 may form a static field in the magnet assembly 10. The gradient coil unit 21 may form a gradient field in the static field. The RF coil unit 22 may excite atomic nuclei by applying RF pulses, and may receive an echo signal from the atomic nuclei.

The controller 30 may control the operation of the magnet assembly 10. The controller 30 may include a static field controller 31 and a pulse sequence controller 32. The static field controller 31 may control intensity and direction of a static field formed by the static field coil unit 20. The pulse sequence controller 32 designs a pulse sequence suitable for a diagnosis region or diagnosis purpose of the subject and controls the gradient coil unit 21 and the RF coil unit 22 according to the designed pulse sequence.

In addition, the MRI apparatus 1 may include a gradient applying unit 42 (e.g., gradient applier) applying a gradient signal to the gradient coil unit 21, and an RF applying unit 43 (e.g., RF applier) applying an RF signal to the RF coil unit 22. The pulse sequence controller 32 controls the gradient applying unit 42 and the RF applying unit 43, such that pulse sequence controller 32 can adjust the gradient field formed in the static field and RF signals applied to the atomic nuclei.

The image processing unit 36 may receive an echo signal generated from the atomic nuclei so as to generate magnetic resonance (MR) images.

In addition, the MRI apparatus 1 may include a user interface (UI) 33. The UI 33 may include a user operating unit 34, and a main display unit 35 (e.g., main display).

The MRI apparatus 1 may include a user operating unit 34, which may receive a control command related to overall operation of the MRI apparatus 1 from the user. In particular, the user operating unit 34 may produce a pulse sequence based on a received control command related to a pulse sequence.

A control state caused by the controller 30 and images formed by the image processing unit 36 may be displayed on the main display unit 34. A user may diagnose a health state of an object 40 indicating a patient through images displayed on the main display unit 34.

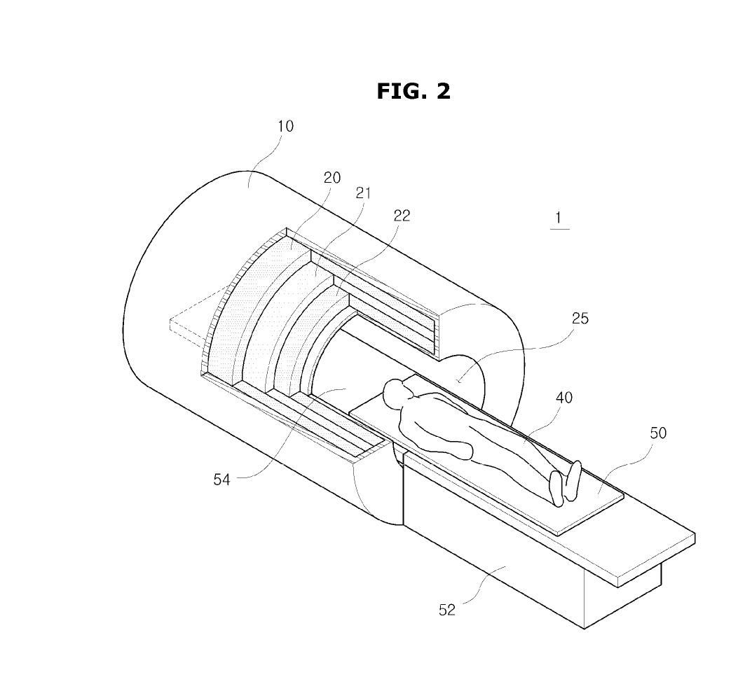

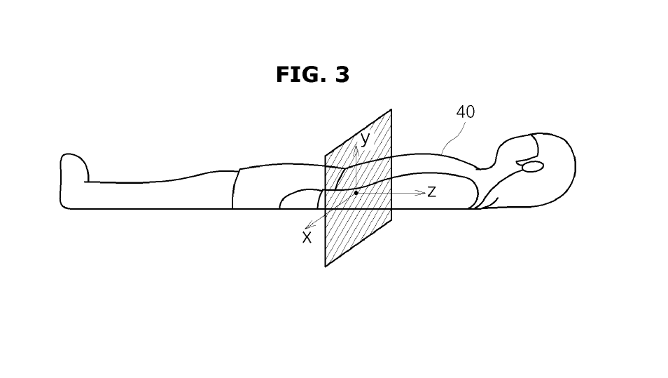

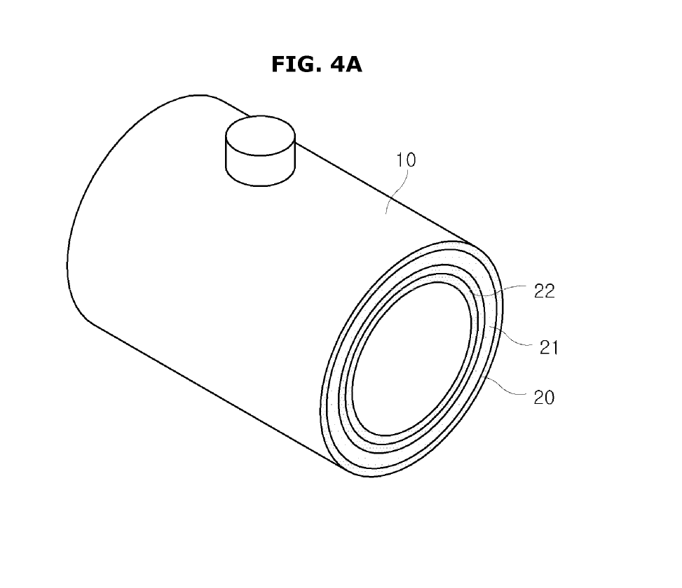

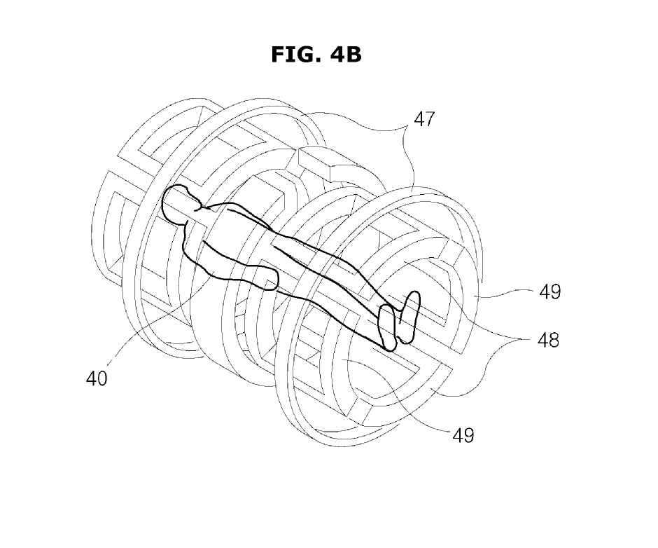

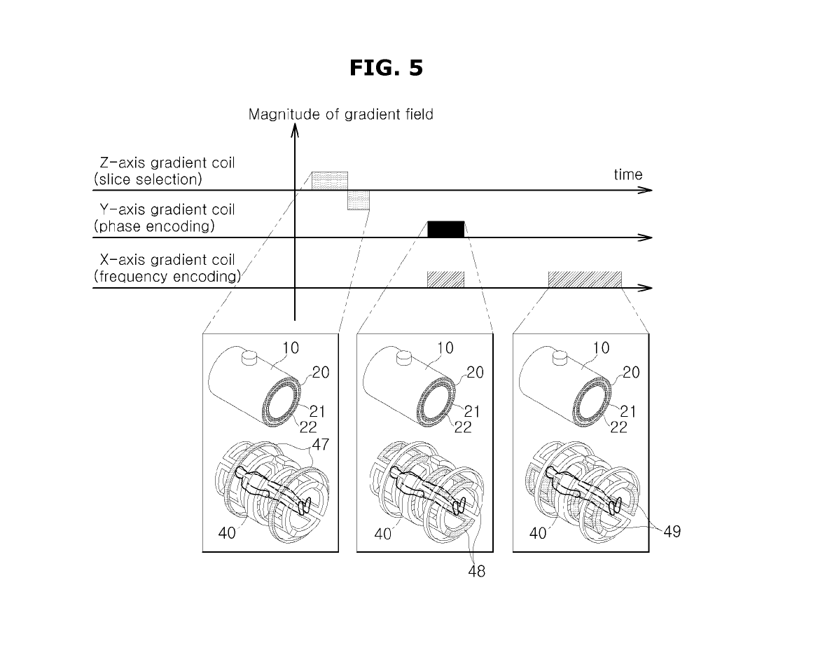

FIG. 2 is a view schematically illustrating an external appearance of the magnetic resonance imaging (MRI) apparatus according to an exemplary embodiment. FIG. 3 is a view illustrating a space in which an object is placed, in the X-axis, Y-axis, and Z-axis. FIGS. 4A and 4B are views illustrating a configuration of a magnet assembly and a configuration of gradient coils of the MRI apparatus according to an exemplary embodiment. FIG. 5 shows a gradient coil unit and a pulse sequence for use in the MRI apparatus.

Hereinafter, operation of the MRI apparatus according to an exemplary embodiment will be described in detail with reference to FIG. 1.

Referring to FIG. 1, the magnet assembly 10 takes the form of a hollow cylinder having an empty inner space. The inner space is referred to as a bore 25. That is, the magnet assembly 10 may be formed to have the bore 25 therein. A transfer table 50 serves to transport the patient 40 lying thereon into the bore 25 for acquisition of a magnetic resonance (MR) signal.

As described above, the magnet assembly 10 may include a static field coil unit 20, a gradient coil unit 21, and an RF coil unit 22.

The static field coil unit 20 may have a structure in which coils are wound around the bore 25. If current is applied to the static field coil unit 20, a static field is formed inside the magnet assembly 10, that is, in the bore. The direction of the static field is generally parallel to the concentric axis of the magnet assembly 10.

If the static field is formed in the bore 25, the atomic nuclei of atoms (e.g., hydrogen atoms) configuring the patient 40 are arranged in the direction of the static field, and perform precession with respect to the direction of the static field. The rate of precession of each atomic nucleus may be indicated as a precession frequency, which may also be referred to as the Larmor frequency, and expressed by the following “Equation 1”.

ω=γB₀ [Equation 1]

Where ω refers to a Larmor frequency, γ refers to a proportional constant, and B₀ refers to an intensity of an external magnetic field. The proportional constant differs for each type of atomic nucleus, the unit of the intensity of the external magnetic field is Tesla (T) or Gauss (G), and the unit of the precession frequency is Hz.

For example, since the hydrogen proton has a precession frequency of 42.58 MHz in an external magnetic field of 1 T and hydrogen occupies the greatest proportion of atoms constituting the human body, the magnetic resonance signal is mainly obtained using the precession of the hydrogen proton in MRI.

The gradient coil portion 21 generates a gradient in the static field formed in the bore 25 to form a gradient magnetic field.

As shown in FIG. 3, an axis parallel with an upward and downward direction from the head to the feet of the patient 40, namely, an axis parallel with a direction of the static field may be referred to as the z-axis, an axis parallel with a left and right direction of the patient 40 may be referred to as the x-axis, and an axis, which is perpendicular to the x-axis and the z-axis and is parallel with an upward and downward direction within the bore 25, may be referred to as the y-axis.

In order to obtain three-dimensional (3D) spatial information, gradient magnetic fields are required for all of the x-, y-, and z-axes. Thus, the gradient coil unit 21 includes three pairs of gradient coils, e.g., the x-axis gradient coil 49, the y-axis gradient coil 48, and the z-axis gradient coil 47.

As shown in FIGS. 4A, 4B, and 5, a z-axis gradient coil 47 is generally composed of a pair of ring coils, and y-axis gradient coils 48 are located over and beneath the patient 40. X-axis gradient coils 49 are located to the left and right of the patient 40.

If direct currents having opposite polarities flow at the two respective z-axis gradient coils 47 in opposite directions, a variation in magnetic field is generated in the z-axis direction, resulting in a gradient magnetic field. FIG. 5 shows formation of a z-axis gradient magnetic field during operation of each z-axis gradient coil 47 as a pulse sequence.

Since a thin slice may be selected as a gradient of the gradient magnetic field formed in the z-axis direction is increased, the z-axis gradient coil 47 is used to select a slice.

When a slice is selected through the gradient magnetic field formed by the z-axis gradient coil 47, all of the spins constituting the slice have the same frequency and phase. Consequently, the spins may not be individually distinguished.

In this case, when a gradient magnetic field is formed in the y-axis direction by the y-axis gradient coil 48, the gradient magnetic field generates a phase shift such that spins constituting lines of the slice have different phases from each other.

That is, when the y-axis gradient magnetic field is formed, the spins in the lines to which a large gradient magnetic field is applied are phase-shifted to a high frequency and the spins in the lines to which a small gradient magnetic field is applied are phase-shifted to a low frequency.

When the y-axis gradient magnetic field disappears, the phase-shift is generated in each of the lines of the selected slice and the lines have different phases from each other. Consequently, the lines may be distinguished from each other.

The gradient magnetic field generated by the y-axis gradient coil 48 is used in phase encoding. FIG. 5 shows formation of the y-axis gradient magnetic field during operation of each y-axis gradient coil 48 as a pulse sequence.

A slice is selected through the gradient magnetic field formed by the z-axis gradient coil 47, and lines constituting the selected slice are distinguished by different phases from each other through the gradient magnetic field formed by the y-axis gradient coil 48. However, since respective spins constituting the lines have the same frequency and phase, the spins may not be individually distinguished.

In this case, when a gradient magnetic field is formed in the x-axis direction by the x-axis gradient coil 49, the gradient magnetic field allows the spins constituting the respective lines to have different frequencies from each other, thereby enabling the spins to be individually distinguished from each other. As such, the gradient magnetic field generated by the x-axis gradient coil 49 is used in frequency encoding.

As described above, the gradient magnetic fields formed by the z-, y-, and x-axes gradient coils encode spatial positions of the respective spins via the slice selection, the phase encoding, and the frequency encoding, respectively.

The gradient coil unit 21 is connected to the gradient applying unit 42, and the gradient applying unit 42 applies a drive signal to the gradient coil unit 21 depending upon a control signal transmitted from the pulse sequence controller 32 so as to generate the gradient magnetic field. The gradient applying unit 42 may include three drive circuits corresponding to the three gradient coils 47, 48, and 49 constituting the gradient coil unit 21.

As described above, the atomic nuclei aligned by the external magnetic field may precess according to the Larmor frequency, and a vector sum of magnetizations of several atomic nuclei may be indicated as one net magnetization M.

Since a z-axis component of the net magnetization may be impossible or very difficult to measure, M_{xy} alone may be measured. Accordingly, the net magnetization should be present on the X-Y plane by excitation of the atomic nuclei, in order to obtain a magnetic resonance signal. An RF pulse tuned to the Larmor frequency of the atomic nuclei has to be applied to a static field for excitation of the atomic nuclei.

The RF coil unit 22 includes a transmission coil to transmit an RF pulse and a reception coil to receive an electromagnetic wave emitted from the excited atomic nuclei, namely, a magnetic resonance signal.

The RF coil unit 22 is connected to the RF applying unit 43, and the RF applying unit 43 applies a drive signal to the RF coil unit 22 depending upon a control signal transmitted from the pulse sequence controller 32 so as to transmit the RF pulse.

The RF applying unit 43 may include a modulation circuit to modulate a high frequency output signal into a pulse signal and an RF power amplifier to amplify the pulse signal.

In addition, the RF coil unit 22 is connected to the image processing unit 36. The image processing unit 36 includes a data collection unit 44 (e.g., data collector), a data storage unit 45 (e.g., data storage), and a data processing unit 46 (e.g., data processor).

The data collection unit 44 may receive data related to the magnetic resonance signal generated by the atomic nuclei. The data collection unit 44 may include a preamplifier, a phase detector, and an A/D converter.

The preamplifier may amplify the magnetic resonance signal received by the reception coil of the RF coil unit 22. The phase detector receives the magnetic resonance signal from the preamplifier to detect a phase. The A/D converter may convert an analog signal obtained through the phase detection into a digital signal. The digital converted magnetic resonance signal may be transmitted to the data storage unit 45.

The data storage unit 45 has a data space constituting a two-dimensional (2D) Fourier space.

The data processing unit 46 may process data received by the data collection unit 44 so as to form magnetic resonance (MR) images. When overall data scan of which is completed is stored in the data storage unit 45, the data processing unit 46 processes the data within the two-dimensional Fourier space using a two-dimensional inverse Fourier transform so as to reconstitute an image of the patient 40. The reconstituted image is displayed on the main display unit 35.

As a method mainly used to obtain the magnetic resonance signal from the atomic nucleus, there is a spin echo pulse sequence. When the RF pulse is applied by the RF coil unit 22, the RF coil unit 22 transmits an RF pulse again at a proper time after a first RF pulse is applied. Strong transverse magnetization appears in the atomic nuclei when time At elapses after transmission of the second RF pulse, with the consequence that the magnetic resonance signal may be obtained. This phenomenon is referred to as the spin echo pulse sequence, and TE (Time Echo) refers to a time required to generate the magnetic resonance signal after application of the first RF pulse.

A level in which the proton is flipped to a degree may be indicated as an angle moving from an axis at which the proton is located before a flip thereof, and is indicated as a 90-degree RF pulse, a 180-degree RF pulse, or the like according to a flip level.

As can be seen from FIG. 2, the MRI apparatus 1 may include a transfer table 50. The transfer table 50 may transport the patient 40 lying thereon into the cavity for acquisition of a magnetic resonance signal.

A transfer table 50 serves to transport the object (e.g., patient 40) lying thereon into the bore 25 for acquisition of a magnetic resonance signal.

The transfer table 50 may move the patient 40 from the outside to the inside of the bore 25, or may also move the patient 50 from the inside to the outside of the bore 25. Therefore, the transfer table 50 may be movably installed to enter or exit the bore 25.

A fixed table 52 may be provided at the outside of the bore 25 to support the transfer table 50, and a transfer guide 54 may be provided in the inside of the bore 25. The fixed table 52 may be integrated with the transfer guide 54. The transfer table 50 may move along the fixed table 50 and the transfer guide 54.

The transfer table 50 may be movable upon receiving driving force from a transfer table driver. The patient 40 may be seated on the transfer table 50. The transfer table 50 may be movably arranged on the fixed table 52. The transfer table driver may be arranged outside the magnet assembly 10 so as to prevent the transfer table driver from entering the bore 25. Assuming that the transfer table driver is arranged outside the magnet assembly 10, even when an electromagnetic motor is used as the transfer table driver, the mutual influence associated with a magnetic field contained in the bore 25 can be minimized, so that load caused by an electromagnetic shield can be reduced. Alternatively, the transfer table driver may have an electromagnetic shield structure in such a manner that the transfer table driver may be affected by a magnetic or electric field contained in the bore 25 or may not affect the magnetic or electric field of the bore 25.

The transfer table driver may include a belt, a motor, etc.

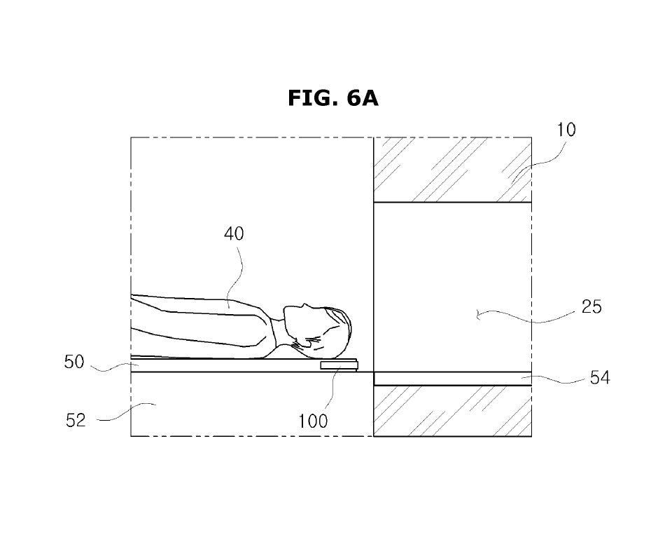

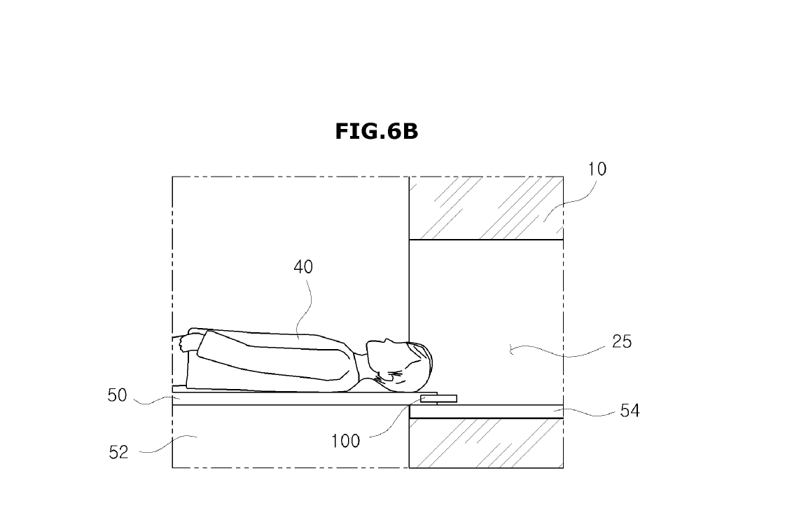

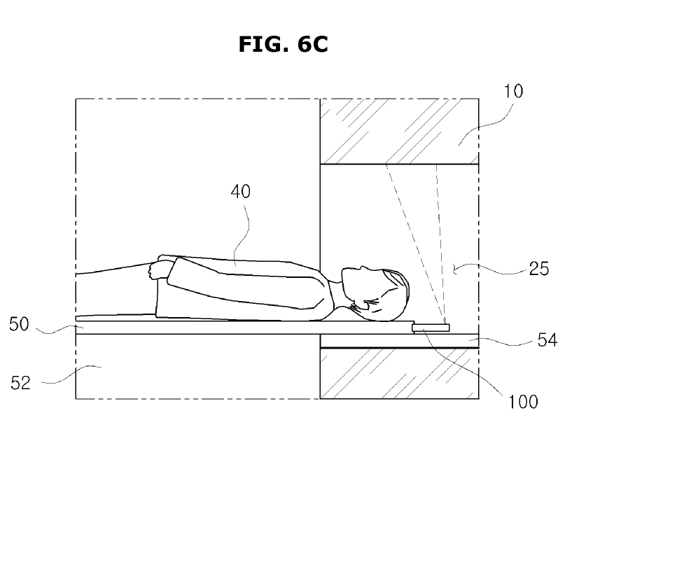

FIGS. 6A, 6B and 6C show the display unit of the MRI apparatus according to an exemplary embodiment. 6A, 6B and 6C schematically show the display unit.

The MRI apparatus may diagnose a health state of the patient 40 transported to the bore 25 by the transfer table 50 as described above. The MRI apparatus may take a predetermined time to diagnose the health state of the patient 40, and the patient 40 placed in the bore 25 may have a fear of small spaces. In addition, the patient 40 may become bored or restless while stayingin the bore 25 due to a long diagnosis time.

For convenience of the patient 40, the MRI apparatus 1 may include an in-bore display unit (IBD) 100 (e.g., in-bore display). The display unit 100 may provide a predetermined image to the patient 40 during inspection.

For example, the display unit 100 may display a TV program or movie thereon such that the patient 40 does not feel bored, and may display images of a guardian of the patient 40 such that the patient 40 may feel a sense of security. In addition, the display unit 100 may display instructions needed for diagnosis such that the patient 40 may easily follow the instructions.

The display unit 100 may be installed at the transfer table 50. As described above, the transfer table 50 may move horizontally to enter or exit the bore 25, and may also move vertically for the patient 40 lying thereon. Therefore, if the display unit 100 is installed to be exposed at the outside of the transfer table 50, there is a risk that the display unit 100 is damaged or broken.

The MRI apparatus 1 according to an exemplary embodiment may provide the display unit 100 to be movably coupled to the transfer table 50.

As can be seen from FIG. 6A, the display unit 100 may be installed in the transfer table 50. If images are displayed for the patient 40, the display unit 100 may be exposed to the outside of the transfer table 50. That is, the display unit 100 may be movably connected to the transfer table 50 in a manner that the display unit 100 can enter or exit the inside of the transfer table 50.

As can be seen from FIGS. 6A to 6C, if the transfer table 50 moves from the outside to the inside of the bore 25, the display unit 100 may move from the inside to the outside of the transfer table 50. The display unit 100 exposed to the outside may display images on the inside of the bore 25 as shown in FIG. 6C.

As can be seen from FIGS. 6C to 6A, if the transfer table 50 moves from the inside to the outside of the bore 25, the display unit 100 moves from the outside to the inside of the transfer table 50. As a result, the display unit 100 designed to move in upward and downward directions of the transfer table 50 can be prevented from being damaged.

The display unit 100 may be movably installed in response to movement of the transfer table 50. Because of characteristics of the MRI apparatus 1, it may be difficult to mount an additional power source to the display unit 100 designed to display images on the inside of the bore 25. In more detail, if an additional power source is mounted to the display unit 100 configured to move into the bore 25, a mutual influence between the additional power source and a magnetic or electric field contained in the bore 25 may occur. Accordingly, the display unit 100 may move by power source of the transfer table 50. That is, the display unit 100 may receive a driving force from the transfer table driver, so that the display unit 100 may be movably installed.

If the transfer table 50 enters the bore 25 as shown in FIGS. 6A and 6B, the display unit 100 may move out of the transfer table 50. In addition, if the transfer table 50 moves out of the bore 25 as shown in FIGS. 6B and 6A, the display unit 100 may enter the transfer unit 50.

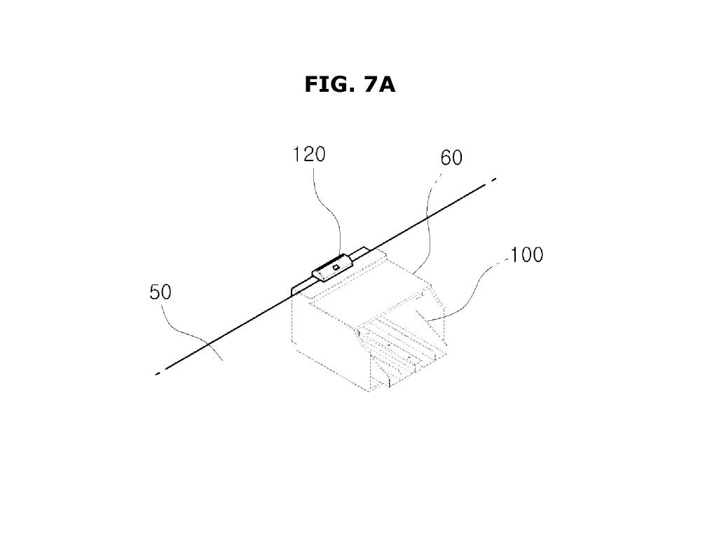

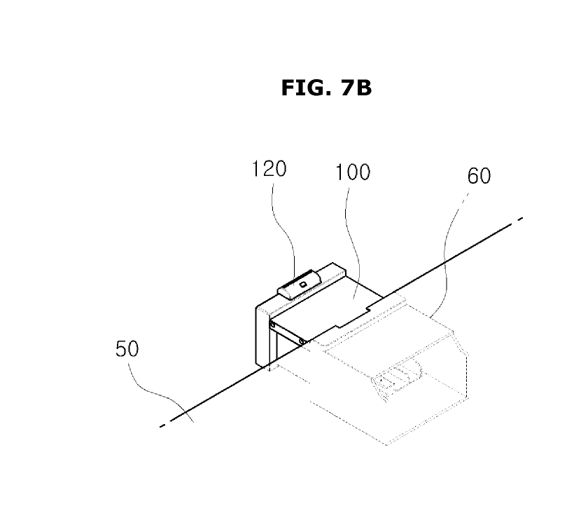

FIGS. 7A and 7B show the in-bore display unit installed at the transfer table of the MRI apparatus according to an exemplary embodiment.

Referring to FIGS. 7A and 7B, the transfer table 50 may include a reception unit 60 (e.g., reception housing) in which the display unit 100 is installed. The reception unit 50 may be provided to be recessed at one side of the transfer table 50. The reception unit 60 may be integrated with the transfer table 50, or may be configured as an additional member coupled to the transfer table 50.

The display unit 100 may be seated in the reception unit 60. The display unit 100 may be movably installed to enter or exit the reception unit 60.

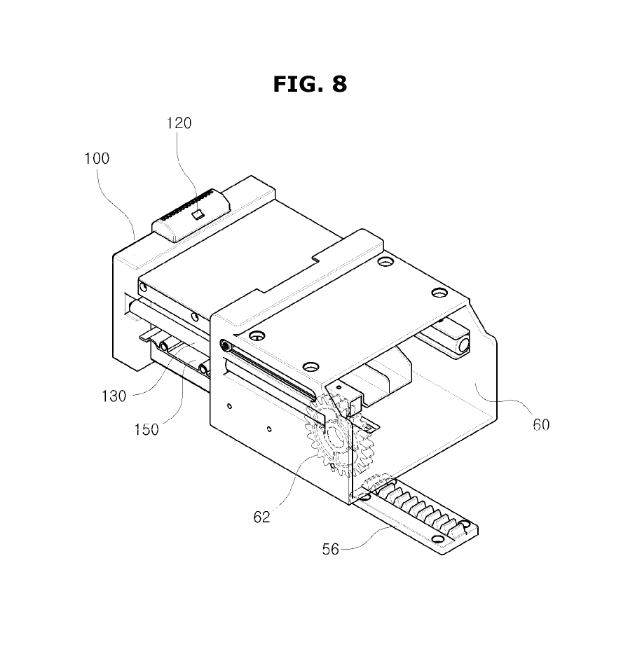

As can be seen from FIG. 7A, the reception unit 60 may be provided at one side of the transfer table 50, and the display unit 100 may be arranged in the reception unit 60. As can be seen from FIG. 7B, the display unit 100 may move out of the reception unit 60. In this case, the display unit 100 may move away from the transfer table 50 so that the display unit 100 can provide images to the patient 40. In addition, the display unit 100 may re-enter the reception unit 60, so that the display unit 100 can be accommodated in the transfer table 50. FIG. 8 shows the reception unit, the display unit, and a second sawtooth of the MRI apparatus according to an exemplary embodiment. Hereinafter, a first sawtooth 62 may include a pinion. The second sawtooth 56 may include a fixed rack. A third sawtooth 110 may include a mobile rack.

As described above, a transfer guide 54 may be located at the inside of the bore 25. The transfer guide 54 may guide or direct the movement of the transfer table 50. A second sawtooth 56 may be placed at one side of the transfer guide 54.

The transfer table 50 may include a first sawtooth 62 that is rotatably installed. More particularly, the first sawtooth 62 may be rotatably coupled to the reception unit 60. The first sawtooth 62 may be provided to correspond to the second sawtooth 56, and may be arranged to contact the second sawtooth 56. Therefore, the transfer table 50 may move along the transfer guide 54 in such a manner that the first sawtooth 62 rotates by the second sawtooth 56.

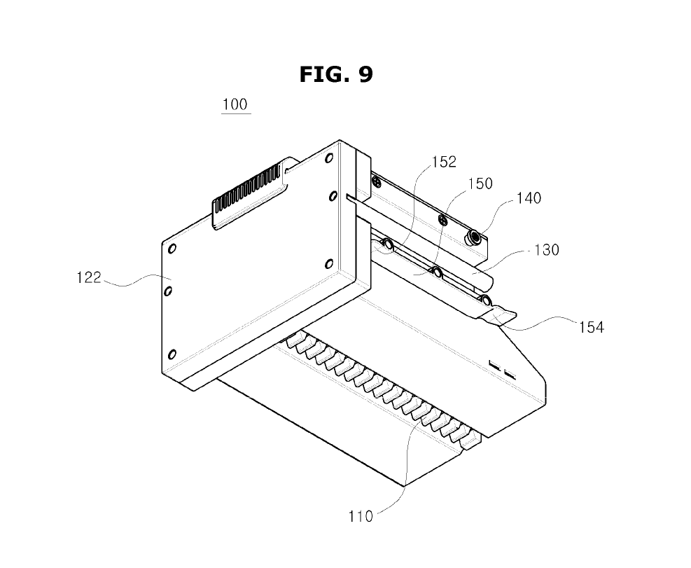

The display unit 100 may include a third sawtooth 110 (See FIG. 9) corresponding to the first sawtooth 62. The third sawtooth 110 may be fixed to the display unit 100. The third sawtooth 110 may be arranged to contact the first sawtooth 62. Accordingly, the third sawtooth 110 and the display unit 100 may move by the rotating first sawtooth 62.

That is, one end of the first sawtooth 62 may contact the third sawtooth 110, and the other end thereof may contact the second sawtooth 56. Therefore, the first sawtooth 62 contacting the second sawtooth 56 rotates in response to the movement of the transfer table 50, and the display unit 100 may be movable by the third sawtooth 110 moving by rotation of the first sawtooth 62.

The display unit 100 and the reception unit 60 will hereinafter be described in detail.

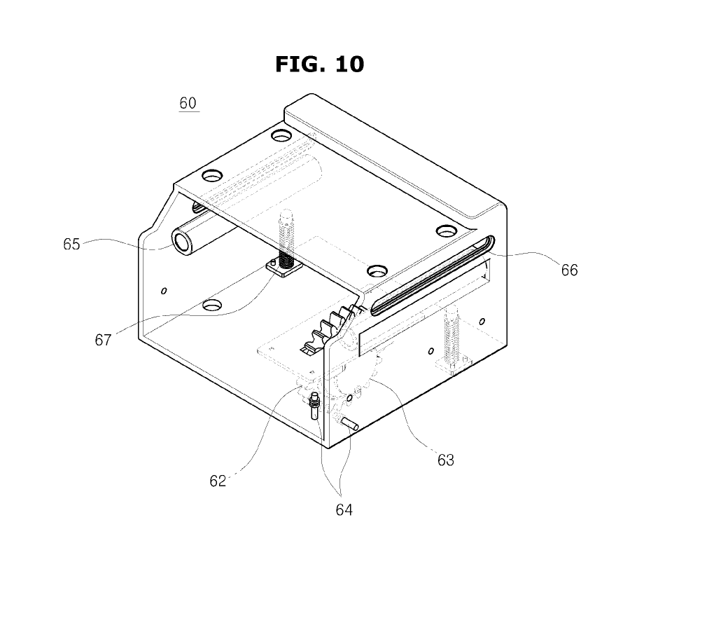

FIG. 9 shows the display unit of the MRI apparatus according to an exemplary embodiment. FIG. 10 is a view illustrating the reception unit of the MRI apparatus according to an exemplary embodiment.

As described above, the display unit 100 may include a third sawtooth 110, and the reception unit 60 may include a first sawtooth 62. As can be seen from FIG. 6, the third sawtooth 110 may be fixed to the bottom of the display unit 100.

The reception unit 60 may include a first-sawtooth installation unit 63 by which the first sawtooth can be rotatably installed. The first-sawtooth installation unit 63 may be placed below the reception unit 60, and may fix the first sawtooth 62 to be rotatably moved. As shown in FIG. 10, the first sawtooth 62 may be installed at the first-sawtooth installation unit 63, and at least some parts thereof may be located in the reception unit 60.

Referring to FIGS. 7A, 7B and 8, the display unit 100 may include a projector 120 for displaying images on the inside of the bore 25. The projector 120 may display images at one side of the bore 25 by emission of a laser beam. As can be seen from FIG. 6C, the projector 120 may be installed in a manner that images can be displayed at one side of the bore 25 located in the viewing direction of the patient's eyes.

The projector 120 may be located at one end of an upper portion of the display unit 100. As can be seen from FIG. 7A, the projector 120 may be exposed to the outside even when the display unit 100 is seated in the transfer table 50. Accordingly, the display unit 100 may be movably installed to guarantee an exit angle of the projector 120.

A control panel unit 122 may be provided below the projector 120. A variety of devices for operating the projector 120 may be provided at the control panel unit 122. The projector 120 may have a mechanical operation structure shielded from the magnetic or electric field contained in the bore 25. In more detail, if the projector 120 has a separate projector driver such as a motor, the projector 120 may be affected by the magnetic or electric field contained in the bore 25, and the image quality may be deteriorated. Therefore, the projector 120 may have a mechanical structure instead of an electromagnetic structure.

At least one of the reception unit 60 and the display unit 100 may include a withdrawal sensor 64. The withdrawal sensor 64 may be installed to detect whether the display unit 100 moves out of the reception unit 60. For example, the withdrawal sensor 64 may be installed at one side of the reception unit 60 as shown in FIG. 10.

The withdrawal sensor 64 may emit light, and may detect the light reflected from an object spaced apart from the withdrawal sensor 64 by a predetermined distance. Therefore, if the display unit 100 is located in the reception unit 60, the withdrawal sensor 64 may sense the reflected light, such that a user can recognize that the display unit 100 is located in the reception unit 60.

If the display unit 100 is withdrawn from the reception unit 60, an object reflecting light is not located at a predetermined distance at which the object can be detected by the withdrawal sensor 64, so that the withdrawal sensor 64 may not detect the reflected light. Accordingly, it can be recognized that the display unit 100 is exposed to the outside.

In addition, the display unit 100 may include a guide shaft 130. The reception unit 60 may include a withdrawal guide 65 including the guide shaft 130. The guide shaft 130 may be provided at both sides of the display unit 100. The withdrawal guide 65 may be arranged at both sides of the reception unit 60 such that the withdrawal guide 65 can correspond to the guide shaft 130.

As the guide shaft 130 moves along the withdrawal guide 65, the display unit 100 may move in a predetermined direction. As a result, light emitted from the projector 120 can be formed at a correct position of the bore 25 located in a viewing direction of the patient 40.

In addition, the display unit 100 may include an auxiliary guide 140 configured to guide movement within a predetermined range. The auxiliary guide 140 may be provided, as a protrusion shape, at both sides of the display unit 100.

The reception unit 60 may include a guide groove 66 in which the auxiliary guide 140 is accommodated. The guide groove 66 may be provided at both sides of the reception unit 60 such that the guide groove 66 can correspond to the auxiliary guide 140. The guide groove 66 may be formed in the shape of a long groove extended by a movement distance of the display unit 100.

The display unit 100 may move in a manner that the auxiliary guide 140 can slide along the guide groove 66. The auxiliary guide 140 contacts one end of the guide groove 66, so that the display unit 100 can move by a predetermined distance.

In addition, the display unit 100 may include a stopper member 150. The stopper member 150 may be formed to fix the display unit 100 at a predetermined position. The stopper member 150 may be formed in the shape of a flat panel protruded from both sides of the display unit 100. The stopper member 150 may include a first fixing unit 152 and a second fixing unit 154 that have upward convex shapes.

The reception unit 60 may include an elastic member 67 corresponding to the stopper member 150. The elastic member 67 may be arranged to contact one side of the stopper member 150. If the elastic member 67 contacts the first fixing unit 152 and the second fixing unit 154, the elastic member 67 is expanded and inserted into the first fixing unit 152 and the second fixing unit 154, resulting in the occurrence of resistance to the movement of the display unit 100.

As shown in FIG. 9, the first fixing unit 152 and the second fixing unit 154 may be spaced apart from each other. If the in-bore display unit is seated in the reception unit 60, the elastic member 67 and the first fixing unit 152 are arranged to contact each other, resulting in the occurrence of resistance to the movement of the display unit 100.

As described above, the display unit 100 moves in response to rotation of the first sawtooth 62, and the elastic member 67 is compressed and separated from the first fixing unit 152. If the display unit 100 moves to a predetermined position at which the exit angle of the projector 120 can be guaranteed, the second fixing unit 154 may be mounted to the elastic member 67. Accordingly, resistance to movement of the display unit 100 may occur.

That is, the stopper member 150 and the elastic member 67 may be provided in a manner that the display unit 100 is fixed to a predetermined position in response to external force other than force caused by the movement of the display unit 100 affected by rotation of the first sawtooth 62.

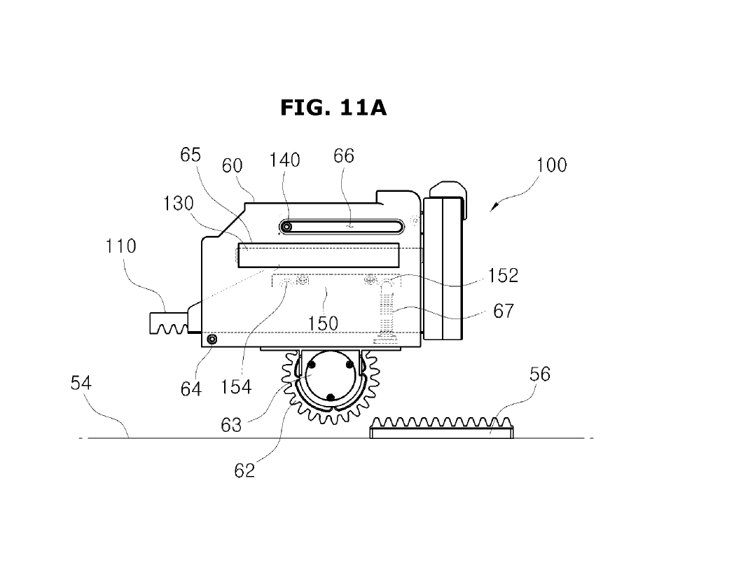

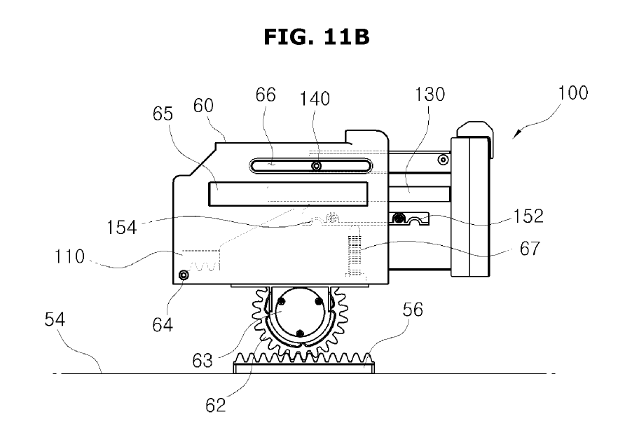

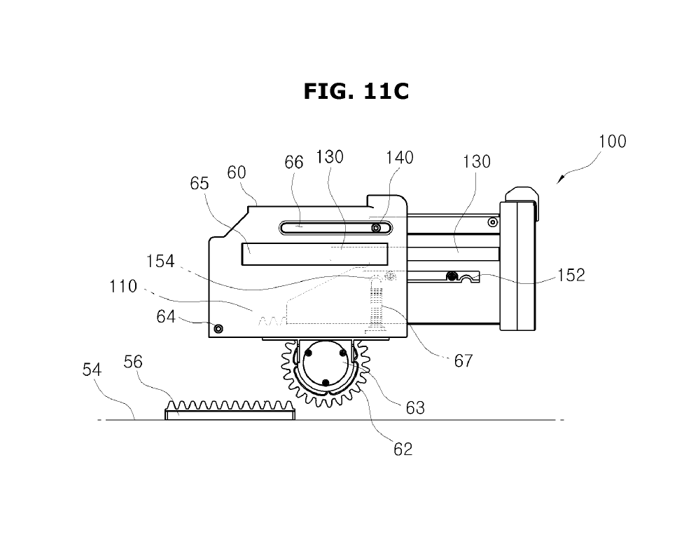

FIGS. 11A, 11B and 11C are conceptual diagrams illustrating movement of the in-bore display unit of the MRI apparatus according to an exemplary embodiment.

FIG. 11A is a first state showing a state before the first sawtooth 62 contacts the second sawtooth 56. FIG. 11B is a second state in which the first sawtooth 62 is passing through the second sawtooth 56. FIG. 11C is a third state in which the first sawtooth 62 has passed through the second sawtooth 56. In the first to third states, the first sawtooth 62 contacts the third sawtooth 110.

In the first state, the display unit 100 is seated in the reception unit 60, so that the withdrawal sensor 64 may detect light reflected by the display unit 100. The guide shaft 130 is seated in the withdrawal guide 65, and the auxiliary guide 140 is arranged at one end of the guide groove 66. The elastic member 67 is designed to be inserted into the first fixing unit 152.

In the second state, the first sawtooth 62 contacts the second sawtooth 56 and rotates by a predetermined angle. The third sawtooth 110 moves by the rotating first sawtooth 62, so that the display unit 100 moves in a predetermined direction. The guide shaft 130 may move along the withdrawal guide 65, and the auxiliary guide 140 may move along the guide groove 66. The elastic member 67 may be compressed by the stopper member 150.

In the third state, the display unit 100 moves by a predetermined distance. The withdrawal sensor 64 is unable to detect the reflected light, so that an exposed state of the display unit 100 can be confirmed. The auxiliary guide 140 is located at the other end of the guide groove 66, and the elastic member 67 is inserted into the second fixing unit 154.

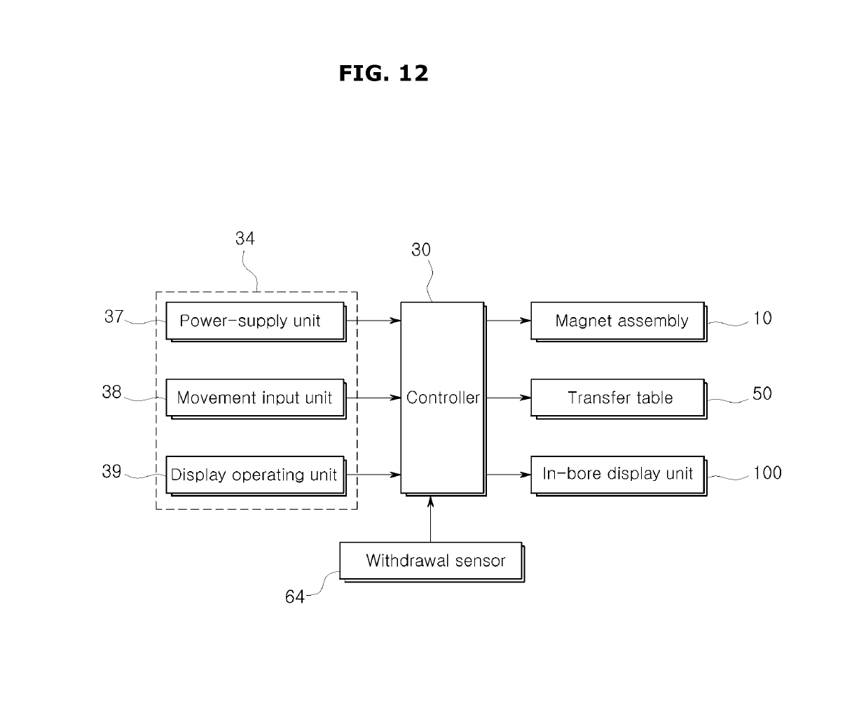

FIG. 12 is a control block diagram illustrating the MRI apparatus according to an exemplary embodiment.

Referring to FIG. 12, the MRI apparatus 1 may include a controller 30 and a user interface including a user operating unit 34. The user operating unit 34 may include a power-supply unit 37, a movement input unit 38, and a display operating unit 39.

In response to a signal being input to the power-supply unit 37, the controller 30 may control the magnet assembly 10. In addition, the controller 30 may move the transfer table 50 in response to the signal being input to the movement input unit 38. As described above, the transfer table 50 may be movable upon receiving driving force from a belt or the like.

In addition, the controller 30 may operate the display unit 100 in response to a signal being input to the display operating unit 39. Alternatively, the controller 30 may confirm the position of the display unit 100 using the withdrawal sensor 64, and may operate the display unit 100.

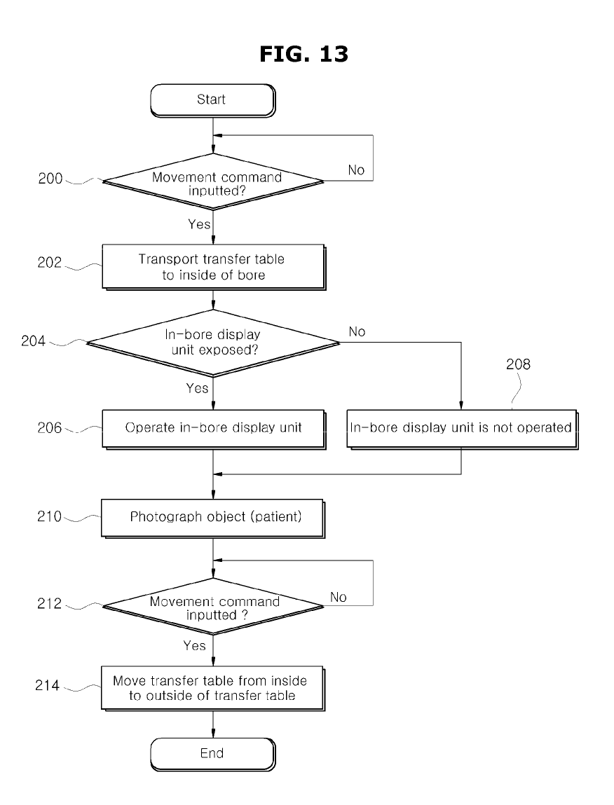

FIG. 13 is a flowchart illustrating a method for controlling the MRI apparatus according to an exemplary embodiment.

For diagnosis through the MRI apparatus 1, the patient 40 lies on the transfer table 50. As described above, the transfer table 50 moves upward and downward along the fixed table 52, so that the patient 40 can be easily seated on the transfer table 50.

If the seated state of the patient 40 is confirmed, the user may input movement of the transfer table 50 to the movement input unit 38 in operation 200. Accordingly, the controller 30 drives the transfer table 50 so that the transfer table 50 moves from the outside to the inside of the bore 25. As described above, since the transfer table 50 moves, the display unit 100 is exposed to the outside of the transfer table 50.

In operation 204, it is determined whether the display unit 100 has normally moved using the withdrawal sensor 64. That is, it is determined whether the projector 120 is arranged in a manner that images can be displayed at one side of the bore 250 located in the viewing direction of the patient 40.

If operation 204 indicates that the display unit 100 has normally moved such that the display unit 100 is withdrawn from the reception unit 60, the user may operate the projector 120 through the display operating unit 39 in operation 206. If operation 204 indicates that the display unit 100 has not normally moved such that the display unit 100 is not withdrawn from the reception unit 60, the user may not operate the projector 120 in operation 208. Alternatively, if the display unit 100 is sensed as being normally moved by the withdrawal sensor 64, the controller 30 can automatically operate the display unit 100.

In order to photograph the patient 40 located in the bore 25, an operator may operate the magnet assembly 10 through the power-supply input unit 37 in operation 210. If the display unit 100 is operating, the patient 40 may view images displayed by the projector 120 during a diagnosis time.

Upon completion of obtaining MRI images, the user may input a command for movement of the transfer table 50 to the movement input unit 38 in operation 212. The transfer table 50 moves from the inside to the outside of the bore 25 in operation 214, such that the display unit 100 can move into the transfer table 50.

The patient 40 who has been completely inspected can be easily seated on or separated from the transfer table 50 by vertical movement of the transfer table 50 and the fixed table 52. In this case, the display unit 100 is disposed in the transfer table 50, so that there is no risk of breaking the display unit 100.

As is apparent from the above description, the in-bore display unit is exposed to the outside in response to movement of a transfer table, such that the in-bore display unit can be prevented from being broken down.

In addition, the in-bore display unit can be transferred by a power source needed for movement of the transfer table.

Although a few exemplary embodiments have been shown and described, it would be appreciated by those skilled in the art that changes may be made in these exemplary embodiments without departing from the principles and spirit of the exemplary embodiments, the scope of which is defined in the claims and their equivalents.

What is claimed is:

1. A magnetic resonance imaging apparatus comprising:
a magnet assembly;
a transfer table configured to move into the magnet assembly or out of the magnet assembly; and
a display configured to move into the transfer table or move out of the transfer table.

2. The magnetic resonance imaging apparatus according to claim 1, wherein the display is configured to move into or out of the transfer table in response to movement of the transfer table.

3. The magnetic resonance imaging apparatus according to claim 1, wherein at least a portion of the display is provided in the transfer table.

4. The magnetic resonance imaging apparatus according to claim 3, wherein:
the display is configured to move out of the transfer table in response to the transfer table moving into the magnet assembly.

5. The magnetic resonance imaging apparatus according to claim 3, wherein the display is configured to move into the transfer table in response to the transfer table moving out of the magnet assembly.

6. The magnetic resonance imaging apparatus according to claim 1, wherein:
the transfer table comprises a rotatably installed first sawtooth; and
the display comprises a third sawtooth corresponding to the first sawtooth.

7. The magnetic resonance imaging apparatus according to claim 6, wherein:
the first sawtooth is configured to rotate in response to movement of the transfer table; and
the third sawtooth is configured to rotate based on rotation of the first sawtooth and thereby move the display.

8. The magnetic resonance imaging apparatus according to claim 6, further comprising:
a bore provided in the magnet assembly; and
a transfer guide provided in the bore so as to guide movement of the transfer table,
wherein the transfer guide comprises a second sawtooth corresponding to the first sawtooth.

9. The magnetic resonance imaging apparatus according to claim 8, wherein:
the transfer table is configured to move along the transfer guide in a manner that the first sawtooth rotates based on movement of the second sawtooth; and
the display is configured to move based on rotation of a third sawtooth moving based on rotation of the first sawtooth.

10. The magnetic resonance imaging apparatus according to claim 1, wherein:
the transfer table comprises a reception housing which houses the display,
wherein the reception housing is recessed at one side of the transfer table.

11. The magnetic resonance imaging apparatus according to claim 9, wherein the display is configured to move into and out of the reception housing.

12. The magnetic resonance imaging apparatus according to claim 11, wherein at least one of the reception housing and the display comprises a withdrawal sensor configured to detect whether the display is withdrawn from the reception housing.

13. The magnetic resonance imaging apparatus according to claim 10, wherein:
the reception housing comprises a rotatably installed first sawtooth; and
the display comprises a third sawtooth configured to move based on rotation of the first sawtooth.

14. The magnetic resonance imaging apparatus according to claim 13, further comprising:
a bore formed in the magnet assembly,
wherein one side of the first sawtooth contacts the third sawtooth, and
the other side of the first sawtooth contacts a second sawtooth fixed at the inside of the bore.

15. The magnetic resonance imaging apparatus according to claim 1, further comprising:
a bore formed in the magnet assembly,
wherein the display comprises a projector to display an image on an inside of the bore.

16. The magnetic resonance imaging apparatus according to claim 15, wherein the projector is installed in a manner that an image is displayed at one side of the bore located in a viewing direction of a patient on the transfer table.

17. The magnetic resonance imaging apparatus according to claim 15, wherein the projector is shielded from a magnetic field or electric field generated in the bore.

18. The magnetic resonance imaging apparatus according to claim 1, further comprising:
a bore formed in the magnet assembly,
wherein the display is configured to display an image on an inside of the bore.

19. A method for controlling a magnetic resonance imaging apparatus having a magnet assembly in which a bore is formed, the method comprising:
moving a transfer table from an outside of the bore to an inside of the bore;
moving a display out of the transfer table in response to the moving of the transfer table to the inside of the bore;
operating the display to display an image on the inside of the bore;
capturing an image of an object located on the inside of the bore on the transfer table;
moving the transfer table from the inside to the outside of the bore; and
moving the display into the transfer table in response to the moving of the transfer table to the outside of the bore.

20. The method according to claim 19,
wherein the moving of the transfer table to the inside of the bore comprises moving the transfer table along a transfer guide located in the bore; and
wherein the moving of the transfer table to the outside of the bore comprises moving the transfer table along the transfer guide.

21. The method according to claim 20, wherein:
the transfer table comprises a rotatably installed first sawtooth; and
the transfer table is configured to move along the transfer guide in a manner that the first sawtooth rotates based on movement of a second sawtooth provided at the transfer guide.

22. The method according to claim 21, wherein the display comprises a third sawtooth configured to rotate based on rotation of the first sawtooth.

23. The method according to claim 19, wherein:
the display comprises a projector configured to display an image on the inside of the bore.

24. The method according to claim 19, further comprising:
determining whether at least a portion of the display is exposed to the outside of the transfer table.

25. A medical imaging device, comprising:
a magnet assembly comprising a bore;
a transfer table configured to move into and out of the bore; and
a display configured to display an image inside the bore in response to the transfer table moving into the bore.

26. The medical imaging device according to claim 25, wherein the display is configured to move into and out of the transfer table in response to the transfer table moving out of and into the bore, respectively.

27. The medical imaging device according to claim 26, wherein movement of the transfer table supplies power to move the display into and out of the transfer table.
